(19) United States
(12) Patent Application Publication
(10) Pub. No.: US 2020/0412060 A1
(43) Pub. Date: Dec. 31, 2020

(54) ELECTRICAL CONNECTOR STRUCTURE

(71) Applicant: SPEED TECH CORP., TAOYUAN CITY (TW)

(72) Inventors: I-Ting HSIEH, Taoyuan City (TW); Cheng-Hsiang HSUEH, Taoyuan City (TW)

(73) Assignee: SPEED TECH CORP., TAOYUAN CITY (TW)

(21) Appl. No.: 16/680,895

(22) Filed: Nov. 12, 2019

(30) Foreign Application Priority Data
Jun. 26, 2019 (TW) 108122428

(51) Int. Cl. H01R 13/6471; H01R 13/6599; H01R 12/72; H01R 12/73; H01R 13/514; H01R 13/6585; H05K 1/02

(52) U.S. Cl. CPC H01R 13/6471; H01R 13/6599; H01R 12/722; H05K 1/0216; H01R 13/514; H01R 13/6585; H01R 12/73

(57) ABSTRACT

An electrical connector structure is provided. The electrical connector structure includes a housing, a plurality of terminals and a plurality of conductive members. The terminals are disposed in the housing. The conductive members are disposed on a side of the terminals. Two immediately adjacent ones of the conductive members are physically separated and electrically connected.

### RELATED APPLICATIONS

This application claims priority to Taiwan Application Serial Number 108122428, filed Jun. 26, 2019, the disclosure of which is incorporated herein by reference in its entirety.

### BACKGROUND

### Technical Field

The present disclosure relates to an electrical connector structure.

### Description of Related Art

Wired transmission between different electronic devices is mainly achieved through electrical connectors. In recent years, rapid progress has been made in science and technology, and the requirement for transmission bandwidth has increased correspondingly. To meet the increasingly higher demand for bandwidth, it is necessary to raise the frequency of the transmitted electronic signal. However, high frequency signals are susceptible to crosstalk (especially when the signal terminals are too close to each other).

### SUMMARY

In view of the foregoing, one of the objects of the present disclosure is to provide an electrical connector structure that reduces crosstalk.

To achieve the objective stated above, in accordance with an embodiment of the present disclosure, an electrical connector structure includes a housing, a plurality of terminals and a plurality of conductive members. The terminals are disposed in the housing. The conductive members are disposed on a side of the terminals. Two immediately adjacent ones of the conductive members are physically separated and electrically connected.

In one or more embodiments of the present disclosure, the terminals are arranged along a direction. The two immediately adjacent conductive members are arranged along the direction.

In one or more embodiments of the present disclosure, the conductive members are located on a side of the terminals facing the housing.

In one or more embodiments of the present disclosure, the terminals are arranged in two parallel rows. The conductive members are located between the two rows of the terminals and are parallel to the two rows of the terminals.

In one or more embodiments of the present disclosure, the terminals include a plurality of signal terminal pairs and a plurality of third terminals. The signal terminal pairs interleave with the third terminals. Each of the conductive members is electrically connected with at least one of the third terminals.

In one or more embodiments of the present disclosure, the two immediately adjacent conductive members form a gap therebetween. A vertical projection of the gap onto a plane on which the terminals are arranged is between two signal terminals of one of the signal terminal pairs.

In one or more embodiments of the present disclosure, one of the third terminals is physically separated with one of the conductive members immediately adjacent to the third terminal.

In one or more embodiments of the present disclosure, a minimum distance between the third terminal and the conductive member substantially falls within a range from 0.03 mm to 0.3 mm.

In one or more embodiments of the present disclosure, the conductive member has a rib structure extending towards the third terminal. The rib structure is separated from the third terminal by the minimum distance.

In one or more embodiments of the present disclosure, the conductive members and the third terminals are in a one-to-one correspondence.

In one or more embodiments of the present disclosure, the conductive members and the third terminals are in a one-to-many correspondence.

In one or more embodiments of the present disclosure, the two immediately adjacent conductive members are separated by an insulation material.

In one or more embodiments of the present disclosure, the two immediately adjacent conductive members are separated by air.

In one or more embodiments of the present disclosure, the two immediately adjacent conductive members are separated by a distance substantially falling within a range from 0.03 mm to 0.3 mm.

In one or more embodiments of the present disclosure, the electrical connector structure further includes an insulating inner frame disposed in the housing. The terminals are fixedly attached to the insulating inner frame.

In sum, unlike the design of using a common ground found in conventional electrical connectors, the electrical connector structure of the present disclosure includes multiple conductive members that are physically separated and electrically connected for grounding. With said structural configuration, the electrical connector structure of the present disclosure can reduce crosstalk more effectively.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates an assembled view of an electrical connector structure in accordance with an embodiment of the present disclosure taken from a view angle;

FIG. 2 illustrates an assembled view of the electrical connector structure shown in FIG. 1 taken from another view angle;

FIG. 3 illustrates an exploded view of the electrical connector structure shown in FIG. 2;

FIG. 4 illustrates an assembled view of an electrical connector structure in accordance with another embodiment of the present disclosure;

FIG. 5 illustrates an exploded view of the electrical connector structure shown in FIG. 4;

FIG. 6 illustrates a partially enlarged cross-sectional view of the electrical connector structure shown in FIG. 4 taken along line segment N-N′;

FIG. 7 illustrates a partially enlarged cross-sectional view of an electrical connector structure in accordance with another embodiment of the present disclosure;

FIG. 8 illustrates a partially enlarged cross-sectional view of an electrical connector structure in accordance with another embodiment of the present disclosure;

FIG. 9 illustrates a partially enlarged cross-sectional view of an electrical connector structure in accordance with another embodiment of the present disclosure; and

FIG. 10 illustrates a partially enlarged cross-sectional view of an electrical connector structure in accordance with another embodiment of the present disclosure.

### DETAILED DESCRIPTION

For the sake of the completeness of the description of the present disclosure, reference is made to the accompanying drawings and the various embodiments described below. Various features in the drawings are not drawn to scale and are provided for illustration purposes only. To provide full understanding of the present disclosure, various practical details will be explained in the following descriptions. However, a person with an ordinary skill in relevant art should realize that the present disclosure can be implemented without one or more of the practical details. Therefore, the present disclosure is not to be limited by these details.

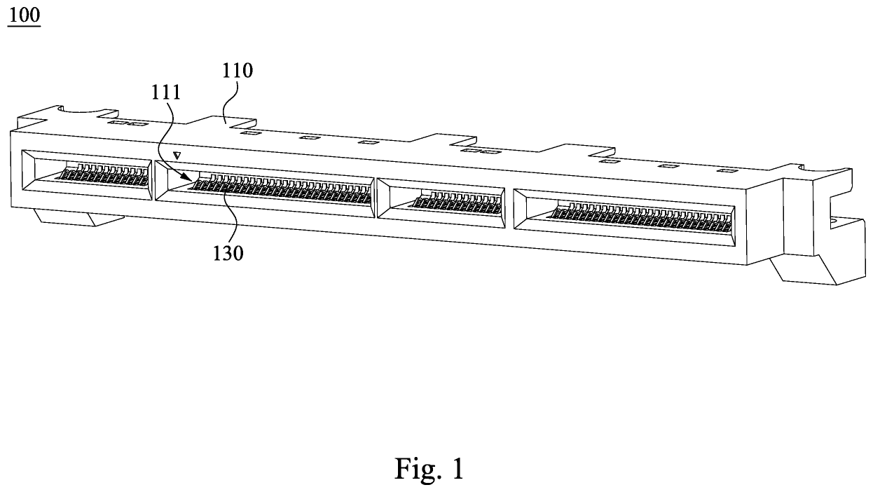

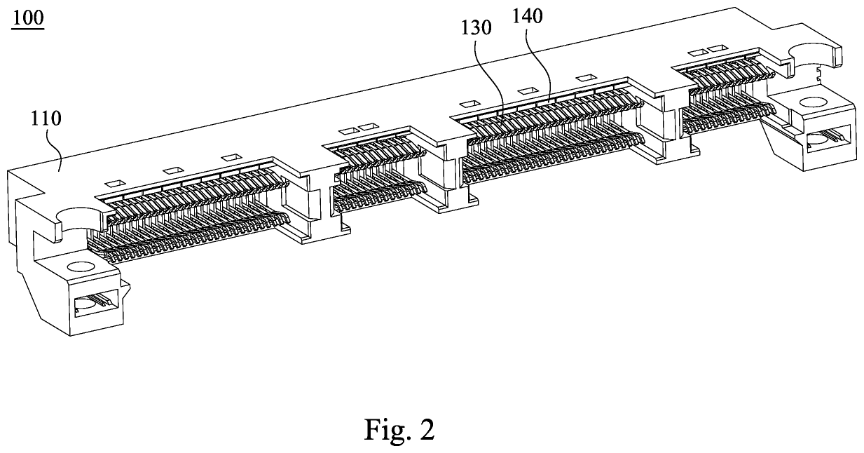

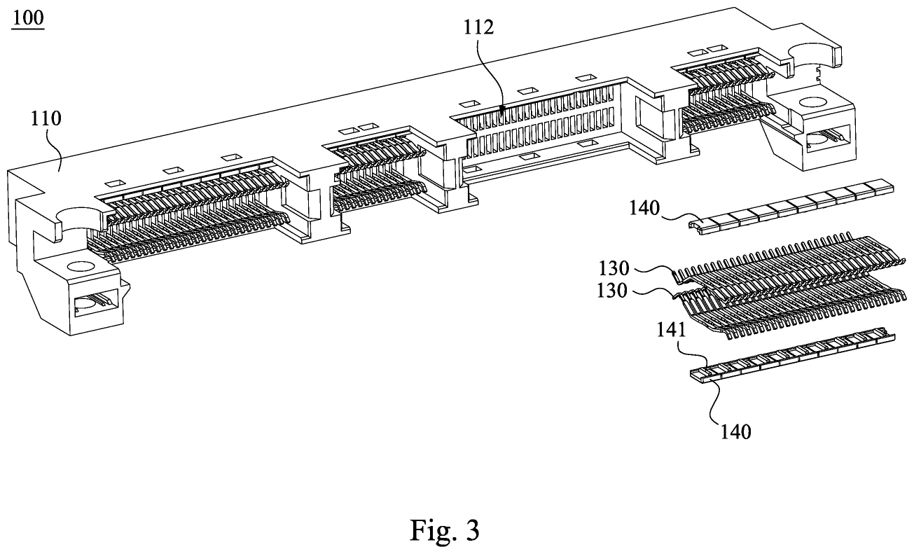

Reference is made to FIGS. 1-3. FIGS. 1 and 2 illustrate assembled views of an electrical connector structure 100 in accordance with an embodiment of the present disclosure taken from two different view angles. FIG. 3 illustrates an exploded view of the electrical connector structure 100 shown in FIG. 2. In the present embodiment, the electrical connector structure 100 is a card edge connector that is configured to be electrically coupled with a circuit board (not depicted). As shown in FIGS. 2 and 3, the electrical connector structure 100 includes a housing 110, a plurality of terminals 130 and a plurality of conductive members 140. The terminals 130 are disposed in the housing 110. The conductive members 140 are located inside the housing 110 and are disposed on a side of the terminals 130. The housing 110 has a socket 111 on its front side (see FIG. 1). The socket 111 is configured to receive a pairing male connector (not depicted).

As shown in FIGS. 2 and 3, the housing 110 further has a plurality of through holes 112 that are in communication with the socket 111 and are configured to allow the terminals 130 to pass through. Specifically, each of the terminals 130 has two opposite ends, one of which extends into the socket 111 via the through holes 112 to electrically couple the pairing male connector (not depicted), and the other protrudes out of the rear side of the housing 110 and is configured to be electrically coupled to the circuit board (not depicted).

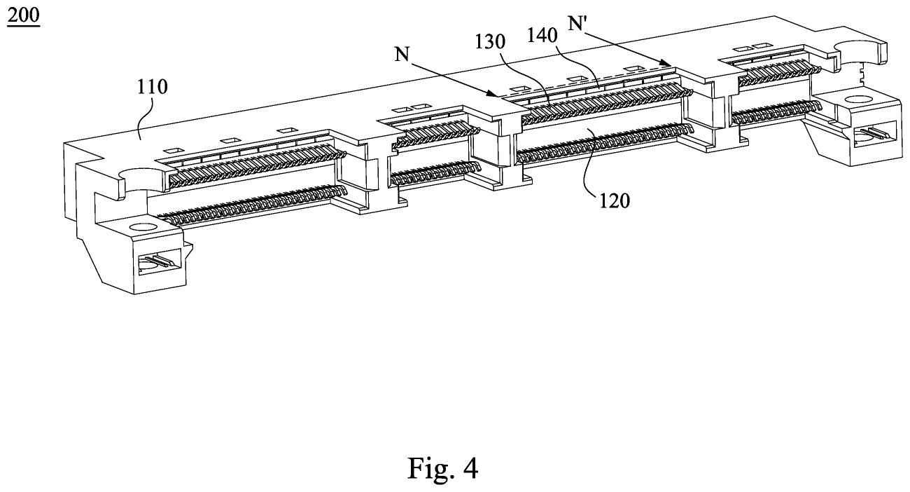

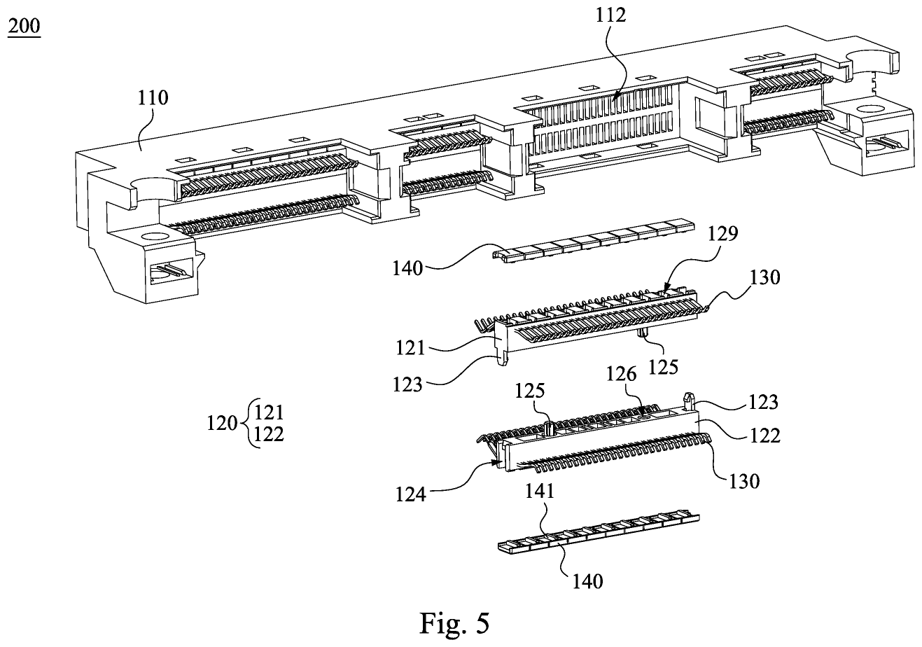

Reference is made to FIGS. 4 and 5. FIG. 4 illustrates an assembled view of an electrical connector structure 200 in accordance with another embodiment of the present disclosure. FIG. 5 illustrates an exploded view of the electrical connector structure 200 shown in FIG. 4. The present embodiment differs from the embodiment shown in FIGS. 2 and 3 in that the electrical connector structure 200 further includes an insulating inner frame 120 disposed in the housing 110 and that the terminals 130 are fixedly attached to the insulating inner frame 120. Specifically, the middle portion of the terminal 130 is embedded in the insulating inner frame 120, and the two exposed ends are configured to be electrically coupled to the pairing male connector and the circuit board respectively (as discussed above).

In some embodiments, the insulating inner frame 120 includes insulating plastic materials and the insulating inner frame 120 is manufactured by means of injection molding. The terminals 130 are embedded into the insulating inner frame 120 during the injection molding process. In some embodiments, the insulating inner frame 120 and the terminals 130 are combined by assembling.

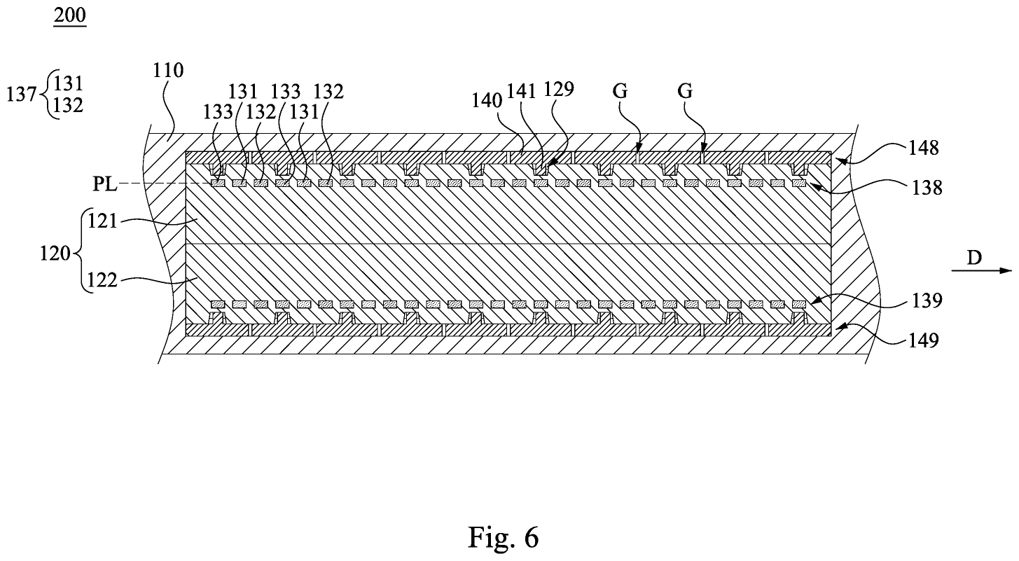

Reference is made to FIG. 6, which illustrates a partially enlarged cross-sectional view of the electrical connector structure 200 shown in FIG. 4 taken along line segment N-N′. The terminals 130 include a plurality of signal terminal pairs 137 and a plurality of third terminals 133. The signal terminal pairs 137 interleave with the third terminals 133. Each of the signal terminal pairs 137 includes two signal terminals 131 and 132. The signal terminals 131, 132 and the third terminal 133 are arranged in the specified order in an interleaved manner along the direction D to form two parallel rows 138 and 139. In some embodiments, the two signal terminals 131 and 132 of the same signal terminal pair 137 form a differential signal pair.

As shown in FIG. 6, the conductive members 140 are located between the housing 110 and the insulating inner frame 120 and are arranged on a side of the terminals 130 facing the housing 110. Specifically, the conductive members 140 are arranged in two parallel rows 148 and 149 along the direction D. Conductive members 140 on the row 148 are arranged on a side of the row 138 facing the top of the housing 110. Conductive members 140 on the row 149 are arranged on a side of the row 139 facing the bottom of the housing 110. In the present embodiment, the conductive members 140 and the third terminals 133 are in a one-to-one correspondence, i.e., for each conductive member 140 there exists exactly one pairing third terminal 133, and for each third terminal 133 there exists exactly one pairing conductive member 140. The conductive member 140 and the corresponding third terminal 133 are electrically connected. In the present embodiment, the conductive member 140 is in close proximity to the corresponding third terminal 133 but does not make contact with the corresponding third terminal 133. In other words, the conductive member 140 and the corresponding third terminal 133 are electrically coupled without making physical contact. In some embodiments, a minimum distance between the conductive member 140 and the corresponding third terminal 133 substantially falls within a range from 0.03 mm to 0.3 mm. In some embodiments, the conductive member 140 contacts the corresponding third terminal 133 to establish an electrical connection therebetween.

The third terminals 133 may act as grounding terminals. In some embodiments, the third terminals 133 may alternatively serve to transmit low frequency signals (e.g., signals less than 500 MHz), identification signals and/or control signals. The third terminals 133 may also be configured for other purposes to take account of the requirements in different application scenarios. In some embodiments, the conductive members 140 include conductive plastic with electrical conductivity ranging from 0.1 S/m to 100 S/m.

As shown in FIG. 6, two immediately adjacent ones of the conductive members 140 (that are arranged side-by-side in the direction D) are physically separated and electrically connected (or electrically coupled). With such a structural configuration, crosstalk may be reduced. The two immediately adjacent conductive members 140 may form a gap G therebetween (i.e., the two immediately adjacent conductive members 140 are separated by air). Alternatively, the two immediately adjacent conductive members 140 may be separated by an insulation material, such as the insulation material inside the housing 110, the insulation material of the insulating inner frame 120 or additional insulation material. In some embodiments, the two immediately adjacent conductive members 140 are separated by a distance substantially falling within a range from 0.03 mm to 0.3 mm. In the embodiment shown in FIG. 6, said distance is the width of the gap G in the direction D. A distance over 0.3 mm may result in insignificant crosstalk reduction, while a distance under 0.03 mm may result in a significant increase in manufacturing complexity for the electrical connector structure 200. In practical applications, keeping the conductive members 140 physically separated and electrically connected may reduce crosstalk by 5 dB to 15 dB.

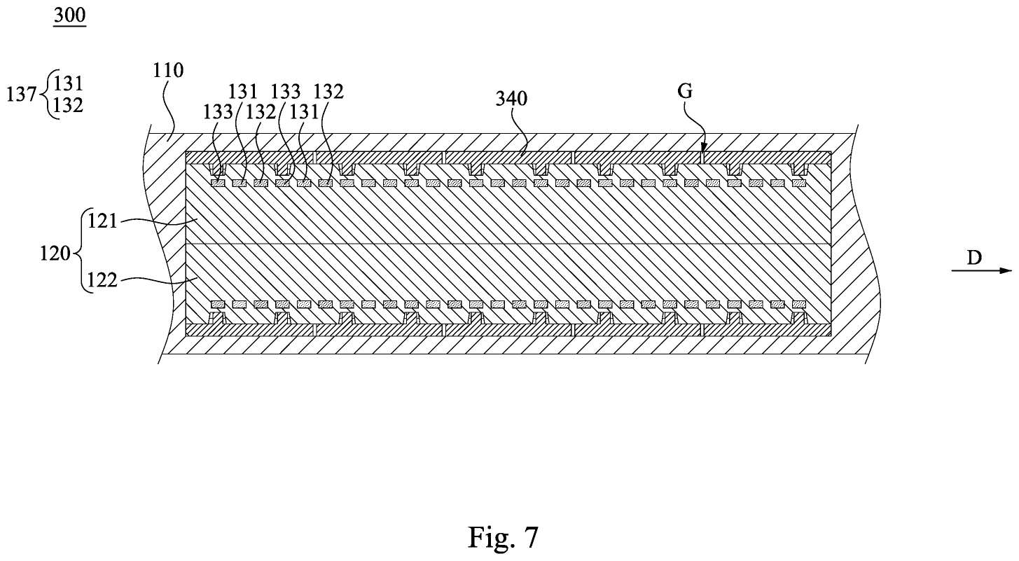

Reference is made to FIG. 7, which illustrates a partially enlarged cross-sectional view of an electrical connector structure 300 in accordance with another embodiment of the present disclosure. The present embodiment differs from the embodiment shown in FIG. 6 in that the conductive members 340 and the third terminals 133 of the electrical connector structure 300 are in a one-to-many correspondence. In other words, each conductive member 340 may be electrically connected with multiple third terminals 133 (e.g., each conductive member 340 is electrically connected with two third terminals 133 as exemplified in FIG. 7, but the present disclosure is not limited in this regard), and two immediately adjacent conductive members 340 are physically separated and electrically connected to reduce crosstalk.

Reference is made back to FIG. 6. In some embodiments, the insulating inner frame 120 has a plurality of recesses 129 each recessed towards the corresponding third terminal 133 from a surface of the insulating inner frame 120 facing the housing 110. The conductive member 140 has a rib structure 141. The rib structure 141 protrudes from a side of the conductive member 140 away from the housing 110 and extends into the corresponding recess 129. The rib structure 141 extends towards the corresponding third terminal 133 but does not contact the corresponding third terminal 133. The conductive member 140 and the corresponding third terminal 133 are kept physically separated, with the minimum distance between the two defined by the distance from the rib structure 141 to the corresponding third terminal 133. In some embodiments, in the direction D, the rib structure 141 and the corresponding third terminal 133 have substantially the same width.

In some embodiments, as shown in FIG. 6, the bottom of the recess 129 is separated from the corresponding third terminal 133, and the end of the rib structure 141 abuts against the bottom of the corresponding recess 129. In other words, the rib structure 141 and the corresponding third terminal 133 are separated by the insulating inner frame 120. In some embodiments, the recess 129 may be further recessed such that the bottom of the recess 129 reaches the corresponding third terminal 133, and the rib structure 141 and the corresponding third terminal 133 are separated by air accordingly. In some embodiments, the rib structure 141 and the corresponding third terminal 133 are separated by the insulation material inside the housing 110. In some embodiments, the distance between the rib structure 141 and the corresponding third terminal 133 (which is the same as the distance between the bottom of the recess 129 and the corresponding third terminal 133 in the embodiment shown in FIG. 6) substantially falls within a range from 0.03 mm to 0.3 mm.

In some embodiments, as shown in FIG. 6, the rib structure 141 is located at the center of the conductive member 140, such that a cross section of the conductive member 140 is symmetric and T-shaped. A vertical projection (i.e., projection along a vertical direction perpendicular to the direction D) of the gap G onto a plane PL on which the terminals 130 are arranged is between two signal terminals 131 and 132 of the corresponding signal terminal pairs 137. A vertical projection of the rib structure 141 onto the plane PL overlaps the corresponding third terminal 133.

Reference is made back to FIG. 5. In some embodiments, the insulating inner frame 120 includes a first frame 121 and a second frame 122. The terminals 130 on the row 138 are fixedly attached to the first frame 121 while the terminals 130 on the row 139 are fixedly attached to the second frame 122. Some of the recesses 129 are located on a surface of the first frame 121 away from the second frame 122 and are paired up with the rib structures 141 of the conductive members 140 on the row 148. The rest of the recesses 129 are located on a surface of the second frame 122 away from the first frame 121 and are paired up with the rib structures 141 of the conductive members 140 on the row 149. In some embodiments, the first frame 121 and the second frame 122 are combined via engaging structures such as a tab 123, a slot 124, a post 125 and a cavity 126. Specifically, the tab 123 and the slot 124 of the second frame 122 are located on its two opposite sides and interlock with the slot 124 (not depicted in FIG. 5, may be structurally identical to the slot 124 of the second frame 122) and the tab 123 of the first frame 121 respectively. The post 125 and the cavity 126 of the second frame 122 are located to a side of the second frame 122 facing the first frame 121 and engage with the cavity 126 (not depicted in FIG. 5, may be structurally identical to the cavity 126 of the second frame 122) and the post 125 of the first frame 121 respectively.

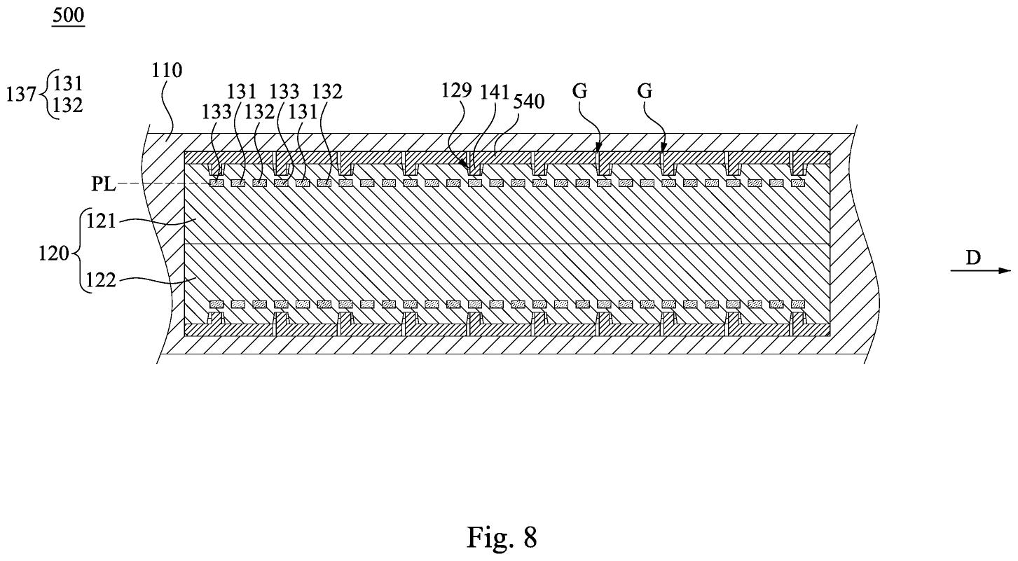

Reference is made to FIG. 8, which illustrates a partially enlarged cross-sectional view of an electrical connector structure 500 in accordance with another embodiment of the present disclosure. The electrical connector structure 500 includes a housing 110, an insulating inner frame 120, a plurality of terminals 130 and a plurality of conductive members 540. Like reference numerals refer to like elements that are substantially identical to those previously described with reference to FIG. 6. Descriptions regarding these elements are not repeated herein for brevity.

In some embodiments, as shown in FIG. 8, the rib structure 141 is located on an end of the conductive member 540 such that a cross section of the conductive member 540 is substantially L-shaped. A vertical projection (i.e., projection along a vertical direction perpendicular to the direction D) of the gap G between two immediately adjacent conductive members 540 onto a plane PL on which the terminals 130 are arranged is between the corresponding signal terminal pair 137 and the corresponding third terminal 133. A vertical projection of the rib structure 141 of the conductive member 540 onto the plane PL overlaps the corresponding third terminal 133.

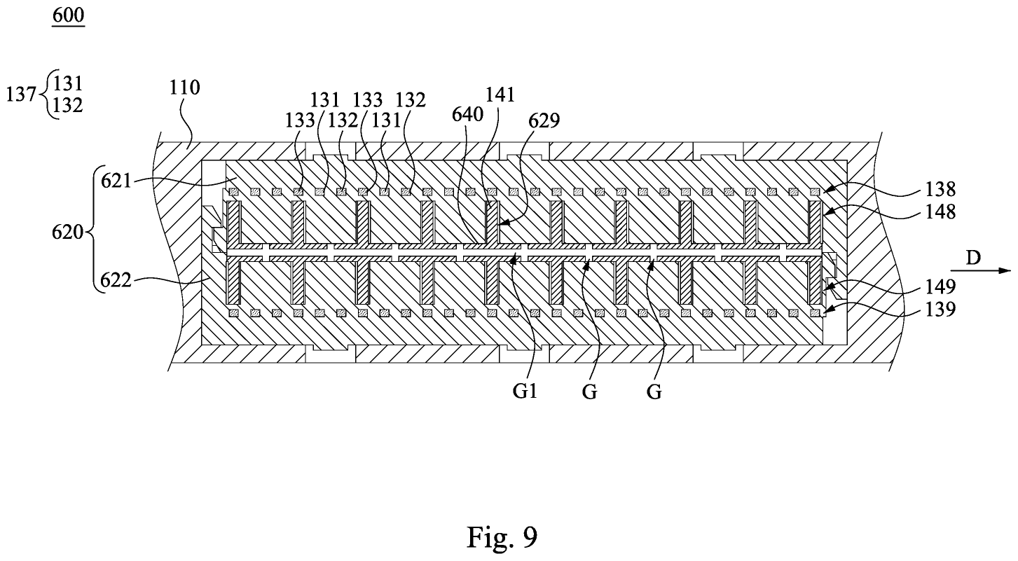

Reference is made to FIG. 9, which illustrates a partially enlarged cross-sectional view of an electrical connector structure 600 in accordance with another embodiment of the present disclosure. The electrical connector structure 600 includes a housing 110, an insulating inner frame 620, a plurality of terminals 130 and a plurality of conductive members 640. Like reference numerals refer to like elements that are substantially identical to those previously described with reference to FIG. 6. Descriptions regarding these elements are not repeated herein for brevity.

In some embodiments, as shown in FIG. 9, the conductive members 640 are disposed inside the insulating inner frame 620 and are arranged in parallel between the two rows 138 and 139 of the terminals 130. In other words, the conductive members 640 are located on a side of the terminals 130 away from the housing 110. The insulating inner frame 620 includes a first frame 621 and a second frame 622 that are assembled together. The first frame 621 has a plurality of recesses 629 each recessed towards the corresponding third terminal 133 from a surface of the first frame 621 facing the second frame 622. Likewise, the second frame 622 has a plurality of recesses 629 each recessed towards the corresponding third terminal 133 from a surface of the second frame 622 facing the first frame 621. Each recess 629 is configured to receive the rib structure 141 of the corresponding conductive member 640. In other words, the conductive member 640 partially extends into the recess 629 to approach the third terminal 133. The conductive members 640 may be arranged such that a gap G1 is formed between conductive members 640 on the two rows 148 and 149 respectively (i.e., conductive members 640 on the two rows 148 and 149 respectively are separated by air). Alternatively, the conductive members 640 on the row 148 may be separated from the conductive members 640 on the row 149 by an insulation material. In some embodiments, the conductive members 640 on the row 148 are separated from the conductive members 640 on the row 149 by the insulation material inside the housing 110.

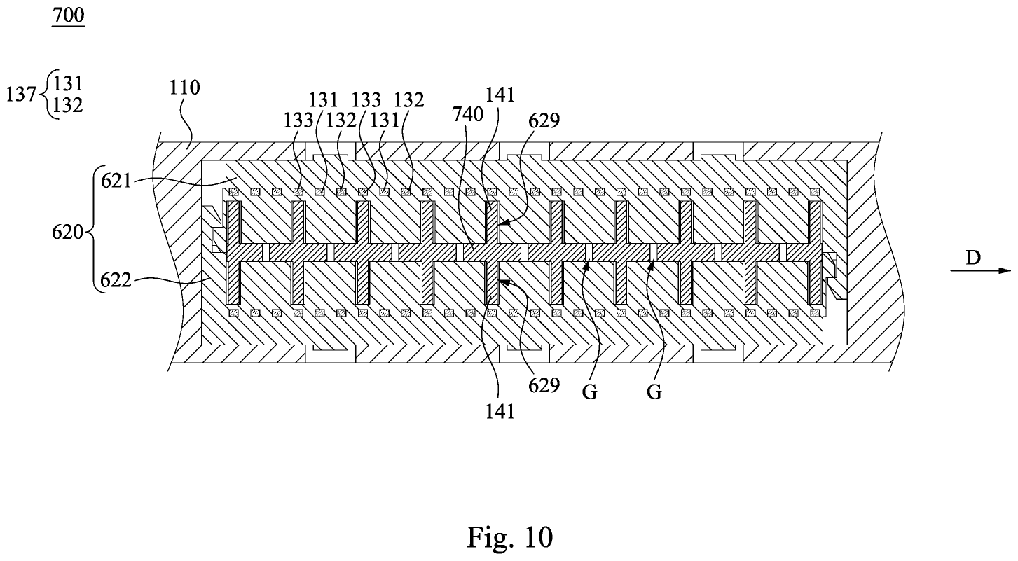

Reference is made to FIG. 10, which illustrates a partially enlarged cross-sectional view of an electrical connector structure 700 in accordance with another embodiment of the present disclosure. The electrical connector structure 700 includes a housing 110, an insulating inner frame 620, a plurality of terminals 130 and a plurality of conductive members 740. Like reference numerals refer to like elements that are substantially identical to those previously described with reference to FIGS. 6 and 9. Descriptions regarding these elements are not repeated herein for brevity.

The present embodiment differs from the embodiment shown in FIG. 9 in that the conductive member 740 of the electrical connector structure 700 has two rib structures 141 on its two opposite sides. The two rib structures 141 extend into the corresponding recesses 629 of the first frame 621 and the second frame 622 respectively to approach the corresponding third terminals 133. In some embodiments, the conductive member 740 may be formed by connecting one of the conductive members 640 on the row 148 to the corresponding conductive member 640 on the row 149 (see FIG. 6).

In sum, unlike the design of using a common ground found in conventional electrical connectors, the electrical connector structure of the present disclosure includes multiple conductive members that are physically separated and electrically connected for grounding. With said structural configuration, the electrical connector structure of the present disclosure can reduce crosstalk more effectively.

Although the present disclosure has been described by way of the exemplary embodiments above, the present disclosure is not to be limited to those embodiments. Any person skilled in the art can make various changes and modifications without departing from the spirit and the scope of the present disclosure. Therefore, the protective scope of the present disclosure shall be the scope of the claims as attached.

1. An electrical connector structure, comprising:
a housing;
a plurality of terminals disposed in the housing; and
a plurality of conductive members disposed on a side of the terminals, wherein two immediately adjacent ones of the conductive members are physically separated, and are electrically coupled through a gap therebetween.

2. The electrical connector structure of claim 1, wherein the terminals are arranged along a direction, the two immediately adjacent conductive members are arranged along the direction.

3. The electrical connector structure of claim 2, wherein the conductive members are located on a side of the terminals facing the housing.

4. The electrical connector structure of claim 2, wherein the terminals are arranged in two parallel rows, the conductive members are located between the two rows and are parallel to the two rows.

5. The electrical connector structure of claim 2, wherein the terminals comprise a plurality of signal terminal pairs and a plurality of third terminals, the signal terminal pairs interleave with the third terminals, and each of the conductive members is electrically connected with at least one of the third terminals.

6. The electrical connector structure of claim 5, wherein a vertical projection of the gap onto a plane on which the terminals are arranged is between two signal terminals of one of the signal terminal pairs.

7. The electrical connector structure of claim 5, wherein one of the third terminals is physically separated with one of the conductive members immediately adjacent to the one of the third terminals.

8. The electrical connector structure of claim 7, wherein a minimum distance between the one of the third terminals and the one of the conductive members substantially falls within a range from 0.03 mm to 0.3 mm.

9. The electrical connector structure of claim 8, wherein the one of the conductive members has a rib structure extending towards the one of the third terminals, the rib structure is separated from the one of the third terminals by the minimum distance.

10. The electrical connector structure of claim 5, wherein the conductive members and the third terminals are in a one-to-one correspondence.

11. The electrical connector structure of claim 5, wherein the conductive members and the third terminals are in a one-to-many correspondence.

12. The electrical connector structure of claim 1, wherein the two immediately adjacent conductive members are separated by an insulation material.

13. The electrical connector structure of claim 1, wherein the two immediately adjacent conductive members are separated by air.

14. The electrical connector structure of claim 1, wherein the two immediately adjacent conductive members are separated by a distance substantially falling within a range from 0.03 mm to 0.3 mm.

15. The electrical connector structure of claim 1, further comprising an insulating inner frame disposed in the housing, the terminals are fixedly attached to the insulating inner frame.
